(19) United States
(12) Patent Application Publication
(10) Pub. No.: US 2016/0225942 A1
(43) Pub. Date: Aug. 4, 2016

(54) SUBSTRATE AND METHOD FOR MANUFACTURING SAME, LIGHT-EMITTING ELEMENT AND METHOD FOR MANUFACTURING SAME, AND DEVICE HAVING SUBSTRATE OR LIGHT-EMITTING ELEMENT

(71) Applicants: NAMIKI SEIMITSU HOUSEKI KABUSHIKIKAISHA, Tokyo (JP); TORAY INDUSTRIES, INC., Tokyo (JP)

(72) Inventors: Natsuko Aota, Tokyo (JP); Hideo Aida, Tokyo (JP); Yutaka Kimura, Akita (JP); Mitsuhito Suwa, Shiga (JP); Masao Kamogawa, Shiga (JP)

(73) Assignees: NAMIKI SEIMITSU HOUSEKI KABUSHIKIKAISHA, Tokyo (JP); TORAY INDUSTRIES, INC., Tokyo (JP)

(21) Appl. No.: 15/022,352

(22) PCT Filed: Aug. 25, 2014
(86) PCT No.: PCT/JP2014/072208

§ 371 Date: Mar. 16, 2016

(30) Foreign Application Priority Data
Sep. 20, 2013 (JP) 2013-194731

(51) Int. Cl. H01L 33/00; H01L 33/20

(52) U.S. Cl. CPC H01L 33/0075; H01L 33/20; H01L 2933/0033

(57) ABSTRACT

A substrate having a desired pattern on a plane thereof and a method for manufacturing same, a light-emitting element and a method for manufacturing same, and a device having the substrate or the light-emitting element are provided which allow the pattern to be formed without any photoresist film, enabling a reduction in the number of steps and a reduction in costs associated with the reduction in the number of steps. A flat substrate is prepared, a dielectric containing a photosensitive agent is formed on a plane of the substrate, the dielectric is patterned to form a desired pattern on the substrate plane, thus, a substrate is obtained which has a pattern of island-shaped protrusions on the plane of the flat substrate and in which the protrusions are configured of the dielectric.

### TECHNICAL FIELD

The present invention relates to a substrate and a method for manufacturing the same, a light-emitting element and a method for manufacturing the same, and a device having the substrate or the light-emitting element.

### BACKGROUND ART

Light emitting diodes (LEDs) are a type of electro luminescence (EL) elements that converge electric energy into light energy using characteristics of compound semiconductors. Light emitting diodes including group 3 to 5 compound semiconductors have been put to practical use. The group 3 to 5 compound semiconductors are direct-transition semiconductors that can operate stably at higher temperatures than elements including other semiconductors. Moreover, the group 3 to 5 compound semiconductors achieve high energy conversion efficiency and have a long life and are often used as various lighting devices, illuminations, electronic equipment, and the like.

A light-emitting element of such a LED (hereinafter referred to as a “light-emitting element” as needed) is formed on a plane of a sapphire (Al₂O₃) substrate. A schematic diagram of the structure of the light-emitting element is depicted in FIG. 17 (see, for example, FIG. 3 in Patent Literature 1). As depicted in FIG. 17, a conventional light-emitting element 100 includes an n-type GaN contact layer (n-GaN layer) 102 formed on a plane of a sapphire substrate 101 via a low-temperature growth buffer layer (not depicted in the drawings) including a GaN-based semiconductor material. An n-type electrode is formed on the n-GaN layer 102. An n-type AlGaN clad layer (not depicted in the drawings; this layer may be omitted), an InGaN light emitting layer (active layer) 103, a p-type AlGaN clad layer 104, and a p-type GaN contact layer 105 are formed on the n-GaN layer 102. Moreover, an ITO (Indium Tin Oxide) transparent electrode 106 as a p-type electrode and a metal electrode are formed on the p-type GaN contact layer 105. As the InGaN light emitting layer 103, a multiple quantum well (MQW) structure configured of an InGaN well layer and an InGaN (GaN) barrier layer is adopted. Furthermore, an n-type electrode layer 107 is formed on an area of the n-GaN layer 102 on which the InGaN light emitting layer 103 is not formed.

Light emitted by the InGaN light emitting layer 103 in the light-emitting element 100 is extracted through the p-type electrode and/or the sapphire substrate 101. In this case, in order to improve light extraction efficiency, dislocation needs to be reduced. However, for the GaN layer grown on the sapphire substrate 101, a difference in lattice constant occurs between sapphire and GaN and leads to threading dislocation in GaN crystals which acts as a dense non-radiative recombination center. The threading dislocation may reduce optical output (external quantum efficiency) and durability life, while increasing leakage current.

Moreover, at wavelengths in a blue region, GaN has a refractive index of approximately 2.4, sapphire has a refractive index of approximately 1.8, and air has a refractive index of 1.0. Thus, a difference in refractive index is approximately 0.6 between GaN and sapphire and as much as approximately 1.4 between GaN and air. The difference in refractive index causes total reflections of light emitted from the InGaN light emitting layer 103 to be repeated between the p-type electrode or the GaN and an air interface or the sapphire substrate 101. The total reflection causes the light to be trapped in the InGaN light emitting layer 103 and self-absorbed or absorbed by the electrode or the like while propagating through the InGaN light emitting layer 103. The light is finally converged into heat. That is, a phenomenon occurs in which the total reflection resulting from the difference in refractive index limits and substantially reduces the light extraction efficiency of the light-emitting element.

A light-emitting element has been disclosed in which, for improved light extraction efficiency, for example, a recessed and protruding pattern is formed on a sapphire substrate plane with GaN layers 102 to 105 and electrodes formed on the recessed and protruding pattern. An available method for forming the recessed and protruding pattern is to etch a surface of the sapphire substrate. Moreover, as a light-emitting element that allows a recessed and protruding pattern to be more efficiently manufactured, a light-emitting element has been disclosed in which a recessed and protruding pattern configured of a dielectric such as SiO₂, ZrO₂, or TiO₂ having a smaller refractive index than GaN is formed on a flat sapphire substrate plane (see, for example, FIG. 1 in Patent Literature 1).

As depicted in FIG. 18, in a light-emitting element 108 disclosed in Patent Literature 1, a pattern of protrusions 109 configured of a dielectric is formed on a plane of a sapphire substrate 101. When the pattern of the protrusions 109 is thus formed on the surface of the sapphire substrate 101, a recessed and protruding refractive-index interface can be formed under the InGaN light emitting layer 103. Thus, when light generated by the InGaN light emitting layer 103 propagates in a lateral direction and is absorbed inside the light-emitting element 108, a portion of the light can be extracted to the outside of the sapphire substrate 101 and the InGaN light emitting layer 103 based on a light scattering effect of the protrusions 109. This enables the light extraction efficiency to be improved. Moreover, light emission efficiency of the light-emitting element 108 can be enhanced without the need to etch the surface of the sapphire substrate 101, and a growth mode of a FACELO (Facet-Controlled Epitaxial Lateral Overgrowth) can be achieved. As a result, a GaN-based light-emitting element can be obtained which has a reduced dislocation density.

### CITATION LIST

### Patent Literature

Patent Literature 1: Japanese Patent Application Laid-open No. 2009-54898

### SUMMARY OF INVENTION

### Technical Problem

However, in Patent Literature 1, a normal photolithography technique is used to form the pattern of the protrusions 109, Therefore, when the protrusions 109 are formed, the following process needs to be executed, Besides an SiO₂ film on which the protrusions 109 are formed, a photoresist film is formed on the SiO₂ film. The photoresist film is patterned via a mask. The SiO₂ film is then patterned by etching using the patterned photoresist film as a new mask. This leads to the need for steps of forming, exposing, and developing the photoresist film and a step of etching the SiO₂ film, resulting in an increased number of steps and increased costs associated with the increased number of steps.

Furthermore, when the protrusions 109 are formed using the photolithography technique and the etching, an exposure step and a development step need to be executed. Therefore, a formable sectional shape of the protrusions 109 is limited to a trapezoid, leading to a reduced degree of freedom for the formable shape of the protrusions. Thus, it has been difficult to use the photolithography technique and the etching to achieve improvement of the light extraction efficiency and production of protrusions with a sectional shape enabling a reduction in the time needed to grow a GaN layer covering the protrusions.

Furthermore, when the surface of the sapphire substrate is patterned by etching using the patterned SiO₂ film as a new mask, a photoresist film is also needed during certain manufacturing steps. This results in an increased number of steps and increased costs associated with the increased number of steps.

The present invention has been developed in view of the above-described circumstances. An object of the present invention is to provide a substrate having a desired pattern on a plane thereof and a method for manufacturing the substrate and a light-emitting element and a method for manufacturing the light-emitting element in which pattern formation can be achieved without any photoresist film to enable a reduction in the number of steps and a reduction in costs associated with the reduction in the number of steps.

### Solution to Problem

The above-mentioned object is accomplished by the present invention described below.

(1) A method for manufacturing a substrate in the present invention includes preparing a flat substrate,

forming a dielectric containing a photosensitive agent on a plane of the substrate, and

patterning the dielectric to form the dielectric having a desired pattern on the plane of the substrate.

(2) In an embodiment of the method for manufacturing a substrate in the present invention, preferably, annealing is performed on the dielectric to form the dielectric having the desired pattern on the plane of the substrate after the dielectric is patterned.

Furthermore, in another embodiment of the method for manufacturing a substrate in the present invention, preferably, the dielectric is post-baked after the dielectric is patterned but before the annealing.

(3) Additionally in another embodiment of the method for manufacturing a substrate in the present invention, preferably, the post-baking is performed within a temperature range of 100 deg C or higher and 400 deg C or lower.

(4) In addition, in another embodiment of the method for manufacturing a substrate in the present invention, preferably, the annealing is performed within a temperature range of 600 deg C or higher and 1,700 deg C or lower.

(5) Furthermore, in another embodiment of the method for manufacturing a substrate in the present invention, preferably, the dielectric is any of a siloxane resin composition, a titanium oxide-containing siloxane resin composition, and a zirconium oxide-containing siloxane resin composition.

(6) Additionally, the method for manufacturing a substrate in another embodiment of the present invention preferably includes applying the dielectric on the plane of the substrate to form the dielectric on the plane of the substrate,

then pre-baking the substrate having the dielectric that has been formed on the plane of the substrate,

then exposing the dielectric with a desired pattern by using a mask,

then developing the exposed dielectric, and

performing the annealing on the dielectric to form the dielectric having the desired pattern on the plane of the substrate.

(7) In addition, the method for manufacturing a substrate in another embodiment of the present invention preferably includes directly patterning the dielectric on the plane of the substrate according to the desired pattern,

then pre-baking the substrate having the dielectric formed on the plane of the substrate,

then exposing the dielectric, and

performing the annealing on the dielectric to form the dielectric having the desired pattern on the plane of the substrate.

(8) Additionally, the method for manufacturing a substrate in another embodiment of the present invention preferably includes applying the dielectric on the plane of the substrate to form the dielectric on the plane of the substrate,

then pressing a mold against the dielectric to cure the dielectric, and

performing the annealing on the dielectric to form the dielectric having the desired pattern on the plane of the substrate.

(9) In addition, a method for manufacturing a substrate in the present invention includes preparing the substrate, and

performing an etching treatment on a surface of the substrate in use of the pattern as a mask to form the desired pattern on the surface of the substrate.

(10) Furthermore, a method for manufacturing a light-emitting element in the present invention includes preparing the substrate, and

forming at least one of a GaN layer, an AlN layer and an InN layer on protrusions and the substrate to manufacture the light-emitting element.

(11) Additionally, a substrate in the present invention includes a pattern including island-shaped protrusions on a flat plane of the substrate, the protrusions being configured of a dielectric. The substrate may be provided in a light source, a display, or a solar cell.

(12) In an embodiment of the substrate in the present invention, preferably the protrusions at least partly have a curved shape (have a curved surface).

(13) Furthermore, in another embodiment of the substrate in the present invention, a dielectric configuring the protrusions preferably contains one of SiO₂, TiO₂, and ZrO₂ as a main component.

(14) Additionally, in another embodiment of the substrate in the present invention, the protrusions preferably have a curved shape generally, no distinction between a top part and side parts, and a curved surface without a flat surface.

(15) In addition, in another embodiment of the substrate in the present invention, the protrusions are preferably semi-spherical.

(16) Furthermore, in another aspect of the substrate in the present invention, each of the protrusions preferably has a round or elliptical flat shape.

(17) Additionally, a substrate in the present invention includes the desired pattern on a surface of the substrate.

(18) In addition, a light-emitting element in the present invention includes at least one of a GaN layer, an AlN layer and an InN layer formed on the protrusions and the substrate.

The light-emitting element is preferably provided in a light source or a display.

### Advantageous Effects of Invention

In any of the inventions in (1), (9), (11), and (17) described above, patterning a dielectric containing a photosensitive agent allows a desired pattern of protrusions to be formed on the substrate plane. Thus, the pattern can be formed on the substrate plane without the need to form any photoresist film. This leads to a reduction in the number of steps, facilitation of the steps, and a reduction in substrate costs associated with the reduction in the number of steps. The resultant substrate can be applied to a light source, a display and a substrate.

Moreover, in the invention in (2) described above, annealing the dielectric after the desired pattern is formed, the desired pattern on the substrate plane can be formed to have any side plane shape without the need to form any photoresist film. Furthermore, removing the photosensitive agent component by annealing allows organic components to be prevented from being mixed into the light-emitting element such as a GaN layer.

Moreover, in the invention in (3) described above, performing post-baking within a temperature range of 100 deg C or higher and 400 deg C or lower enables an increase in flowability of the dielectric. Thus, the entire pattern of the dielectric or a part of the top part/side parts can be rounded into a curved shape, enabling the light extraction efficiency of the light-emitting element to be improved. Moreover, compared to protrusions with a trapezoidal or rectangular sectional shape, the protrusions shaped into a curved shape serve to shorten the time needed to grow the GaN layer in a lateral direction during formation of the GaN layer and the like. Consequently, the time needed to grow the GaN layer can be shortened.

Moreover, in the invention in (4) described above, performing annealing within a temperature range of 600 deg C or higher and 1,700 deg C or lower allows the photosensitive agent component to be removed from the protrusions by the annealing. Thus, organic components can be prevented from being mixed into the light-emitting element such as the GaN layer as described above. This also enables growth of the GaN layer on the protrusions to be prevented or made difficult. Suppressing the growth of the GaN layer on the protrusions allows the FACELO growth mode to be achieved. Consequently, a GaN layer with a reduced dislocation density can be formed.

Moreover, in the invention in (5) described above, a high coverage can be achieved by a siloxane resin composition, a titanium oxide-containing siloxane resin composition, and a zirconium oxide-containing siloxane resin composition, allowing a regular dielectric with a uniform thickness or height and with no uneven feature to be formed on the substrate surface. Moreover, these compositions are not significantly contracted upon being cured, enabling the protrusions to be easily formed on the substrate plane so as to have an appropriate height, an appropriate size, and an appropriate pitch as desired. Furthermore, the siloxane resin composition, the titanium oxide-containing siloxane resin composition, and the zirconium oxide-containing siloxane resin composition are unlikely to be cracked after curing. Consequently, gaps (voids) are unlikely to occur at the interface between the GaN layer and the protrusions during growth of the GaN layer. Therefore, the light-emitting element can be prevented from being subjected to deteriorated electrical characteristics.

Moreover, in the invention in (6) described above, using photolithography to form the desired pattern enables the pattern to be formed on the substrate plane without the need to form any photoresist film. This leads to a reduction in the number of steps, facilitation of the steps, and a reduction in substrate costs associated with the reduction in the number of steps. Furthermore, the photolithography step needs a shortened time, allowing a substrate having a desired pattern on the plane thereof to be produced in a short time.

Moreover, in the invention in (7) described above, using ink jet printing to form the desired pattern allows the pattern to be directly formed, enabling an increase in the degree of freedom for the type of the protrusion pattern.

Moreover, in the invention in (8) described above, using nanoimprinting to form the desired pattern allows a pattern of protrusions with a desired size, a desired pitch, and a desired height to be formed on the substrate plane using simple facilities and at low costs.

Furthermore, in the invention in (10) or (18) described above, the protrusions formed on the surface of the substrate each allow a light scattering effect to be exerted. Therefore, a portion of light absorbed inside the light-emitting element can be extracted to the outside of the substrate and an InGaN light emitting layer. Thus, the light extraction efficiency of the light-emitting element can be improved. The resultant light-emitting element can be applied to a light source, a display, or the like.

Moreover, patterning the dielectric containing the photosensitive agent allows the desired pattern of the protrusions to be formed on the substrate plane. Thus, the pattern can be formed on the substrate plane without the need to form any photoresist film. This leads to a reduction in the number of steps, facilitation of the steps, and a reduction in light-emitting element costs associated with the reduction in the number of steps. Furthermore, a light-emitting element with the light extraction efficiency improved can be manufactured.

Moreover, in the invention in (12) described above, each of the protrusions is partly formed into a curved shape, enabling the light extraction efficiency of the light-emitting element to be improved. Moreover, compared to protrusions with a trapezoidal or rectangular sectional shape, the protrusions shaped into a curved shape serve to shorten the time needed to grow the GaN layer in the lateral direction during formation of the GaN layer and the like. Consequently, the time needed to grow the GaN layer can be shortened.

Moreover, in the invention in (13) described above, when a material configuring the protrusions is a dielectric containing one of SiO₂, TiO₂, and ZrO₂ as a main component, growth of the GaN layer on the protrusions can be prevented or made difficult. Suppressing the growth of the GaN layer on the protrusions allows the FACELO growth mode to be achieved. Consequently, a GaN layer with a reduced dislocation density can be formed.

Moreover, in the invention in (14) or (15) described above, each of the protrusions is formed to generally have a curved surface so as to have a curved shape involving no distinction between a top part and side parts and having no flat surface. This enables the light extraction efficiency of the light-emitting element to be improved. Furthermore, shaping the protrusions into semi-spheres allows the light extraction efficiency to be further improved. Of course, as described above, compared to protrusions with a trapezoidal or rectangular sectional shape, the protrusions formed into a curved shape serve to shorten the time needed to grow the GaN layer in the lateral direction during formation of the GaN layer and the like. Consequently, the time needed to grow the GaN layer can be shortened.

Moreover, in the invention in (16) described above, setting a round or elliptical flat shape for the protrusions enables the patterning step for the dielectric layer to be facilitated. In particular, setting a round flat shape, in addition to the above-described effects, the following effect can be exhibited: even when, for example, light reflection and light refraction and light attenuation by the plurality of protrusions interact (for example, interfere) with one another, the interaction (interference) is made non-directional, allowing light to be emitted uniformly in all directions. Thus, a light-emitting element with high light extraction efficiency can be produced.

### BRIEF DESCRIPTION OF DRAWINGS

FIG. 1 is a schematic diagram depicting the structure of a light-emitting element according to the present invention.

FIG. 2 is a schematic diagram depicting a substrate having a desired pattern on a plane thereof according to the present invention.

FIG. 3(a) is an enlarged side view of the substrate depicted in FIG. 2, and FIG. 3(b) is a partial plan view depicting only protrusions in an enlarged view of the substrate depicted in FIG. 2.

FIG. 4(a) is an enlarged side view depicting a substrate having, on a plane thereof, a pattern of protrusions with an elliptical flat shape according to the present invention, FIG. 4(b) is a partial plan view depicting only protrusions on the substrate depicted in FIG. 4(a), FIG. 4(c) is an enlarged side view of the substrate depicted in FIG. 4(a) as seen in a direction at an angle of 90 degrees with respect to FIG. 4(a), and FIG. 4(d) is a partial plan view depicting only protrusions on the substrate depicted in FIG. 4(c).

FIG. 5(a) is a partial plan view depicting only protrusions with a triangular flat shape according to the present invention, and FIG. 5(b) is a partial plan view depicting only protrusions with a hexagonal flat shape according to the present invention.

FIG. 6 is an enlarged side view depicting a substrate having, on a plane thereof, a pattern of protrusions with a generally polygonal flat shape.

FIG. 6A is an enlarged side view of a substrate in a variation of the substrate, FIG. 6A(a) is an enlarged side view of a substrate that is a variation of the substrate depicted in FIG. 3(a), FIG. 6A(b) is an enlarged side view of a substrate that is a variation of the substrate depicted in FIG. 4(c), and FIG. 6A(c) is an enlarged side view of a substrate that is a variation of the substrate depicted in FIG. 6.

FIG. 7(a) is a protrusion enlarged view of a growth stage of a GaN layer on a trapezoidal protrusion, FIG. 7(b) is a protrusion enlarged view of a growth stage of a GaN layer on a rectangular protrusion, FIG. 7(c) is a protrusion enlarged view of a growth stage of a GaN layer on a protrusion with a pattern generally having a curved shape, and FIG. 7(d) is a protrusion enlarged view of a growth stage of a GaN layer on a protrusion with a top part partly having a curved shape.

FIG. 8 is a schematic diagram illustrating a photolithography manufacturing step that is a form according to a method for manufacturing in the present embodiment.

FIG. 9 is a schematic diagram illustrating an imprinting manufacturing step that is another form according to a method for manufacturing in the present embodiment.

FIG. 10 is a schematic diagram illustrating an ink jet manufacturing step that is another form according to a method for manufacturing in the present embodiment.

FIG. 11 is a sectional view illustrating a process of manufacturing a light-emitting element according to the present invention.

FIG. 12 is an AFM image depicting a sectional shape of a protrusion in an embodiment of the present invention.

FIG. 13 is an AFM perspective image depicting the shape of protrusions in an embodiment of the present invention.

FIG. 14 depicts a lighting device including a light source with a light-emitting element in the present invention.

FIG. 15 depicts a display device including a light source with a light-emitting element in the present invention.

FIG. 16 depicts a solar cell including the substrate in the present invention.

FIG. 17 is a schematic diagram depicting the structure of a conventional light-emitting element.

FIG. 18 is a schematic diagram depicting the structure of another conventional light-emitting element.

### DESCRIPTION OF EMBODIMENTS

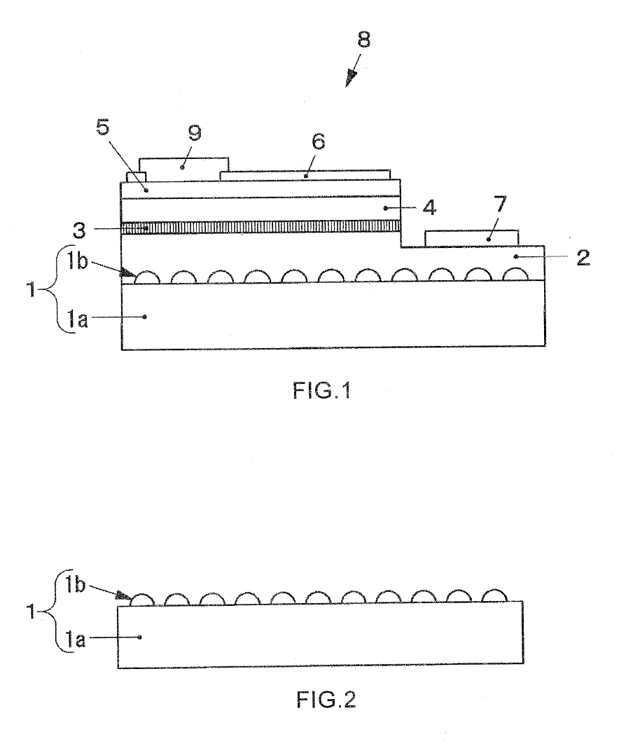

With reference to FIGS. 1 to 7, the present embodiment will be described which is a substrate having a desired pattern on a plane thereof and used to form a GaN layer for a light-emitting element, and a light-emitting element including the substrate. As depicted in FIG. 1, a substrate 1 having a desired pattern on a plane thereof (hereinafter referred to as a “substrate 1” as needed) is a base substrate for a LED light-emitting element 8 (hereinafter referred to as a “light-emitting element 8” as needed). Moreover, as depicted in FIG. 2, the substrate 1 has a pattern located on a plane of a flat substrate 1a and including island-shaped protrusions 1b. Moreover, the protrusions 1b are configured of a dielectric.

The island shape indicates that each of the protrusions 1b has an independent protruding shape from a top part of the protrusion 1b to the height of a surface of the substrate 1a in a thickness direction of the substrate 1a. Therefore, as long as each of the protrusions 1b has an independent protruding shape from the top part of the protrusion 1b to the height of the surface of the substrate 1a, the island shape pattern is established. The protrusions 1b may be separate from one another or side parts of the protrusions 1b may contact each other at bottom surfaces of the protrusions 1b, that is, at the surface of the substrate 1a as the substrate 1a is viewed in a substrate plan direction (an up-down direction in FIG. 1 or FIG. 2).

The protrusions 1b formed on the surface of the substrate 1a each allow a light scattering effect to be exerted. Therefore, a portion of light absorbed inside the light-emitting element 8 can be extracted to the outside of the substrate 1a and the InGaN light emitting layer 3, allowing the light extraction efficiency of the light-emitting element 8 to be improved.

Growth of an n-type GaN contact layer (n-GaN layer) 2 starts at the surface of the substrate 1a between the protrusions 1b, that is, at flat parts that are not the protrusions 1b, and the n-GaN layer 2 extends so as to cover side parts and top parts of the protrusions 1b as the thickness of the n-GaN layer 2 increases. Therefore, the GaN layer is formed so as to cover the surface of the substrate 1a and the pattern of the protrusions 1b.

Any material may be used for the substrate 1a as long as the material allows growth of group 3 to 5 compound semiconductors such as sapphire (Al₂O₃), Si, SiC, GaAs, InP, and spinel. In particular, sapphire is most preferable in view of formation of the group 3 to 5 compound semiconductors. Description will be continued taking a sapphire substrate as an example of the substrate 1a.

When a sapphire substrate is used as the substrate 1a, the surface of the substrate 1a may be selected from a C plane, an A plane, an R plane, and the like as needed or inclined to these surfaces.

Furthermore, the surface of the substrate 1a, where the n-GaN layer 2 starts to grow, is most preferably formed into a mirror plane with a surface roughness Ra of approximately 1 nm or less in order to prevent possible defects during the growth of crystals in the n-GaN layer 2. To form the surface of the substrate 1a into a mirror plane, for example, mirror polishing may be executed on the surface.

A material for the protrusions 1b is a dielectric containing a photosensitive agent. When the protrusions 1b are formed of the dielectric containing the photosensitive agent, a pattern of the protrusions 1b can be formed on the plane of the substrate 1a without any photoresist film (that is, an etching mask for a film to be formed into the protrusions 1b) as described below. Moreover, the dielectric to be formed into the protrusions 1b is preferably a dielectric containing one of SiO₂, TiO₂, and ZrO₂ as a main component. Examples of a material for the dielectric include a siloxane resin composition, a titanium oxide-containing siloxane resin composition, and a zirconium oxide-containing siloxane resin composition.

The siloxane resin composition contains a polymer having a main skeleton based on siloxane bonding. The polymer having the main skeleton based on the siloxane bonding is not particularly limited but preferably has a weight average molecular weight (Mw) of 1,000 to 100,000 and more preferably 2,000 to 50,000 in terms of polystyrene measured by GPC (Gel Permeation Chromatography). An Mw of less than 1,000 leads to low coating performance, and an Mw of more than 100,000 results in low solubility to a developer during pattern formation.

The siloxane resin composition, the titanium oxide-containing siloxane resin composition, and the zirconium oxide-containing siloxane resin composition have high coatability, allowing a regular dielectric with a uniform thickness or height and with no uneven feature to be formed on the surface of the substrate 1a. Moreover, these compositions are not significantly contracted upon being cured, enabling the protrusions 1b to be easily formed on the plane of the substrate 1a so as to have an appropriate height, an appropriate size, and an appropriate pitch as desired. Furthermore, the siloxane resin composition, the titanium oxide-containing siloxane resin composition, and the zirconium oxide-containing siloxane resin composition are unlikely to be cracked after curing. Consequently, gaps (voids) are unlikely to occur at the interface between the protrusions 1b and GaN layers (2 to 5) during growth of the GaN layers. Therefore, the light-emitting element 8 can be prevented from being subjected to deteriorated electrical characteristics. The pitch refers to the shortest of the center distances between the adjacent protrusions 1b.

Moreover, when the material configuring the protrusions 1b is a dielectric containing as a main component any of SiO₂, TiO₂, and ZrO₂, growth of the GaN layers on the protrusions 1b can be prevented or toughened. Suppressing the growth of the GaN layers on the protrusions 1b allows the FACELO growth mode to be achieved. Consequently, GaN layers with a reduced dislocation density can be formed.

Furthermore, when an emission wavelength in the GaN layers in the light-emitting element 8 is set to λ, the size of the protrusion 1b and the pitch between the protrusions 1b are preferably set to at leastλ/(4n) in order to sufficiently scatter or diffract light. The set size of the protrusion 1b varies depending on the flat shape of the protrusion 1b. The size is represented as the length of a radius for a round flat shape, as the length of a radius in a minor axis direction for an elliptical flat shape, or as the length of a constituent side for the protrusion 1b for a polygonal flat shape. Additionally, n refers to the refractive index of the GaN layers and is approximately 2.4 by way of example. When the substrate 1a is used for the light-emitting element 8, the refractive index of the dielectric is different at least from the refractive index of gallium nitride (GaN). In addition, the dielectric preferably has a lower refractive index than gallium nitride (GaN) in order to prevent light from passing toward, the substrate side while improving the brightness of the light-emitting element.

Furthermore, when the total film thickness of all the GaN layers 2 to 5 is 30 μm or less, the pitch between the protrusions 1b is preferably set to 50 μm or less in order to reduce the number of total reflections of light based on scattering or diffraction. Moreover, the pitch between the protrusions 1b is more preferably set to 20 μm or less in order to enhance crystallinity of the GaN layers (that is, to prevent possible pits). The pitch between the protrusions is more preferably set to 10 μm or less, and setting the pitch to 10 μm or less enlarges a light scattering plane to increase the probability of scattering or diffraction, enabling the light extraction efficiency of the light-emitting element 8 to be further improved.

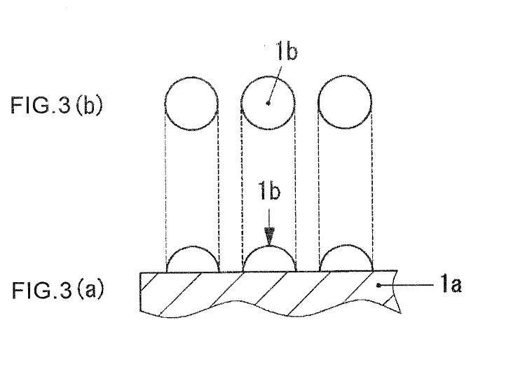

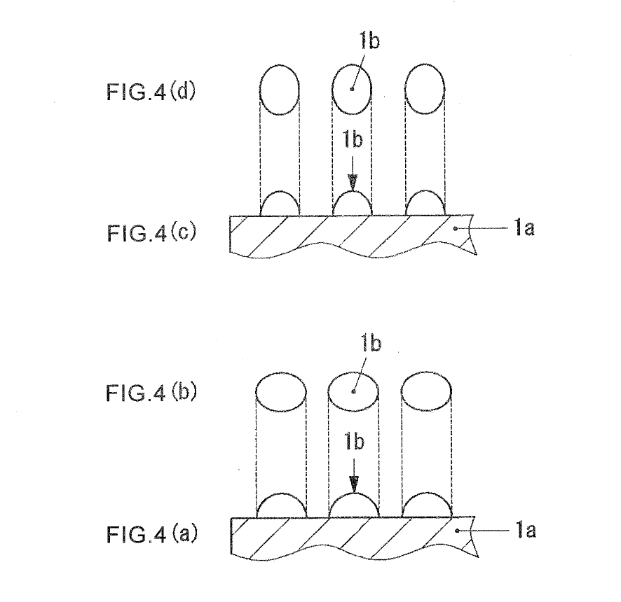

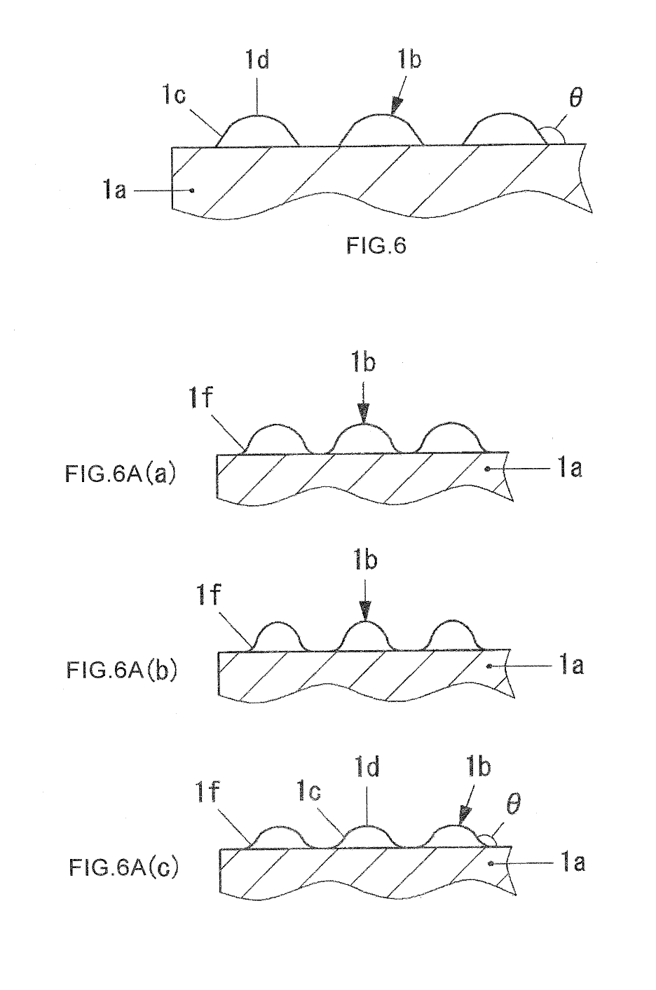

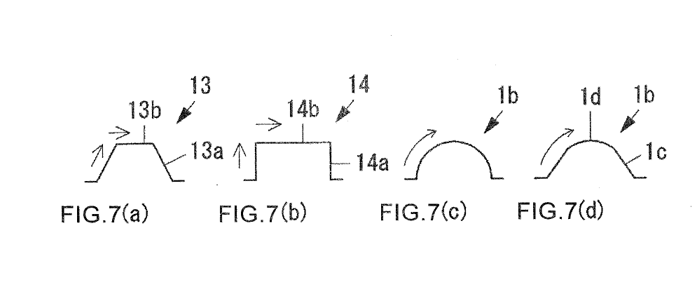

A side shape of each of the protrusions 1b is preferably such that at least a part of the protrusion 1b is formed into a curved shape as depicted in FIG. 3(a), FIGS. 4(a) and 4(c), or FIG. 6. That is, at least a part of the protrusion 1b has a curved surface. The protrusions 1b each partly formed into a curved shape enable the light extraction efficiency of the light-emitting element 8 to be improved. Moreover, compared to protrusions in which a cross-sectional plane thereof taken along a plane perpendicular to the substrate is a trapezoid or a rectangle, the protrusions 1b formed into curved shapes serve to shorten the time needed to grow the GaN layers (2 to 5) in a lateral direction during formation of the GaN layers and the like. Consequently, the time needed to grow the GaN layers can be shortened. More specifically, when an attempt is made to grow a GaN layer in the lateral direction on protrusions 13 with a trapezoidal sectional shape as depicted in FIG. 7(a) or on protrusions 14 with a rectangular sectional shape as depicted in FIG. 7(b), the GaN layer needs to go through two stages of growth; in a first stage, the GaN layer grows at a side part 13a, 14a, and in a second stage, on a Out surface of a top part 13b, 14b. On the other hand, for the protrusions 1b with the entire pattern shaped into a curved shape as depicted in FIG. 7(c), the GaN layer can be formed on the protrusions 1b as a result of continuous lateral growth as depicted by an arrow. This enables a reduction in the time needed to grow the GaN layer. Furthermore, for protrusions 1b each with a top part thereof partly shaped into a curved shape as depicted in FIG. 7(d), the growth of the GaN layer at a side part 1c can be quickly shifted to a top part 1d, enabling a reduction in the time needed to grow the GaN layer. Even for protrusions each with side parts thereof partly shaped into a curved shape, quick growth of the GaN layer is promoted at the side parts, and the growth of the GaN layer can be shifted to a top part. Consequently, the time needed to grow the GaN layer can be shortened.

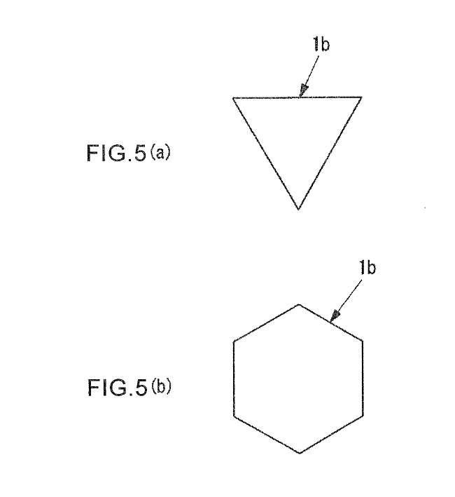

A specific form of the shape of the protrusion 1b is such that the protrusion 1b is formed to have a generally polygonal flat shape as depicted in FIG. 5(a) or 5(b) and an inclined side part 1c as depicted in FIG. 6 and to have a curved surface formed at the protrusion top part 1d.

When a taper angle θ is 90 deg, the protrusion 1b has a rectangular sectional shape. When the taper angle θ is 180 deg, no protrusion 1b is present and the surface of the substrate 1a is flat. To bury the protrusions 1b in the GaN layers, the taper angle θ needs to be at least 90 deg.

The general polygon refers to a triangle or a hexagon, need not be perfectly geometrically polygonal, and includes polygons with a round corner or side for machining reasons or the like. The protrusion 1b with a triangular or hexagonal flat shape may have vertices on a plane substantially parallel to a growth-stable plane of the GaN layer and has, as constituent sides, straight lines crossing the plane substantially parallel to the growth stable plane of the GaN layer.

Furthermore, in an alternative form of the flat shape of the protrusion 1b, the protrusion 1b is preferably formed to generally have a curved surface so as to have a curved shape involving no distinction between the top part and the side parts and having no flat surface, in order to improve the light extraction efficiency and to shorten, the time needed to grow the GaN layers (2 to 5) in the lateral direction. The protrusion 1b is more preferably semi-spherical as depicted in FIG. 3(a). Therefore, each area of the protrusion 1b has a curvature of more than 0, and the protrusion 1b has no corner except for an area where the protrusion 1b is continuous with the substrate 1a. Furthermore, the substrate 1a and the protrusions 1b depicted in FIG. 3(a), FIG. 4(c), and FIG. 6 may have variations as depicted in FIG. 6A. In the variations depicted in FIGS. 6A(a) and 6A(b), the protrusions 1b are each formed to generally have a curved surface 1f having an inflexion point in the middle thereof. Areas of the curved surface if located on laterally opposite sides of the inflexion point each have a curvature with a sign opposite to the sign of the curvature of the curved surface of the top part. Additionally, in the variation depicted in FIG. 6A(c), the protrusion 1b has a curved surface if having a side part is in a part of the curved surface 1f. Areas of the curved surface if located on laterally opposite sides of the side part 1c each have a curvature with a sign opposite to the sign of the curvature of the curved surface of the top part. In this variation, the protrusions 1b are gently continuous with the substrate 1a, promoting the growth of the GaN layers and enabling a reduction in the time needed for the growth. The curved surface 1f may also be formed on the protrusions 1b in FIG. 4(a).

Moreover, the protrusion 1b preferably has a round flat shape as depicted in FIG. 3(b) or an elliptical shape as depicted in FIGS. 4(b) and 4(d). However, even when, for example, light reflection and light refraction and light attenuation by the plurality of the protrusions 1b, 1b, . . . interact (for example, interfere) with one another, these protrusions formed into round shapes make the interaction (interference) non-directional, allowing light to be emitted uniformly in all directions. Thus, a light-emitting element 8 with a high light extraction efficiency can be produced. Therefore, the protrusion 1b with a round flat shape is more preferable. In addition, setting a round or elliptical flat shape enables a patterning step for the dielectric layer described below to be facilitated.

The protrusions 1b formed on the surface of the substrate 1a desirably all have the same size and shape but may be slightly different from one another in size, shape, or the above-described curvature. Furthermore, the array form of the protrusions 1b is not limited but may have a regular pitch as in a lattice-like array or may have an irregular pitch. Alternatively, as the flat shape of the protrusion 1b, both a round or elliptical shape and a generally polygonal shape may be provided on one plane of the substrate 1a.

The light-emitting element 8 is manufactured by forming two or more GaN layers 2 to 5 and a p-type electrode 6 and an n-type electrode layer 7 on the protrusions 1b and the substrate 1a formed on the plane of the substrate 1a as described above. The p′type electrode 6 is formed on a p-type GaN contact layer 5 along with a metal electrode. The n-type electrode layer 7 is formed on an area of the n-GaN layer 2 where the InGaN light emitting layer 3 is not formed. The two or more GaN layers include, for example, the n-type GaN contact layer (n-GaN layer) 2, the InGaN light emitting layer (active layer) 3, a p-type AlGaN clad layer 4, and the p-type GaN contact layer 5, as depicted in FIG. 1. However, the present invention is not limited to this structure. The configuration preferably includes layers of any of group 3 to 5 nitride compound semiconductors having at least a layer with an n-type conductivity, a layer with a p-type conductivity, and a light emitting layer sandwiched between the layer with the n-type conductivity and the layer with the p-type conductivity. The active layer 3 is preferably a layer of any of the group 3 to 5 nitride compound semiconductors represented as Inx Gay Alz N (0≦x≦1, 0≦y≦1, 0≦z≦1, x+y+z=1).

The one of the group 3 to 5 nitride compound semiconductors formed on the substrate 1 is not limited to the GaN layer but may be changed so as to contain at least either an AlN layer or an InN layer. Specifically, for example, a buffer layer of AlN or the like is formed on the substrate 1, and an n-GaN layer 2 is formed on the buffer layer. A layer formed of GaN may be used as the buffer layer.

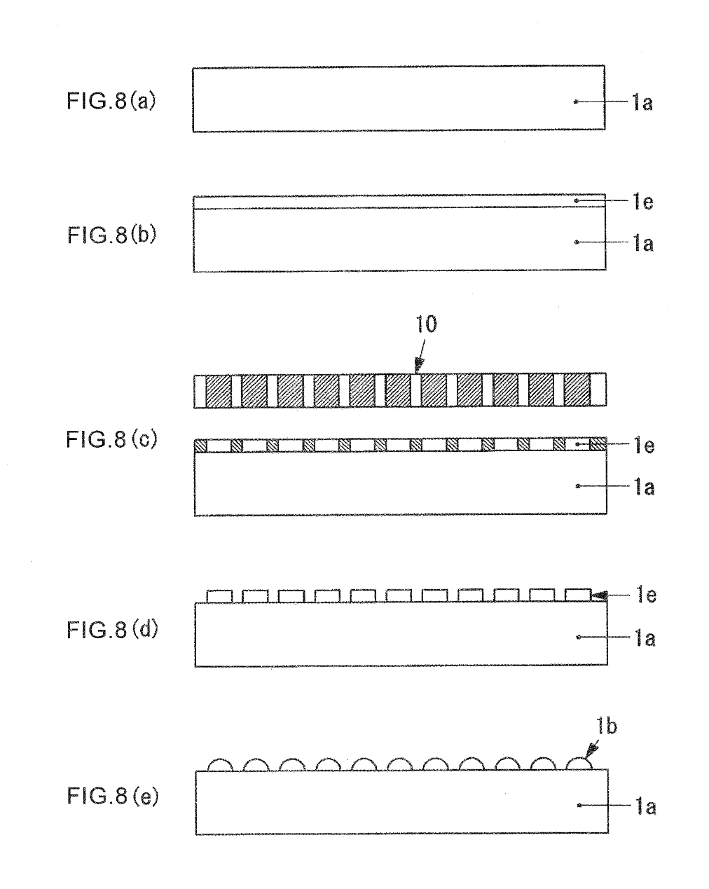

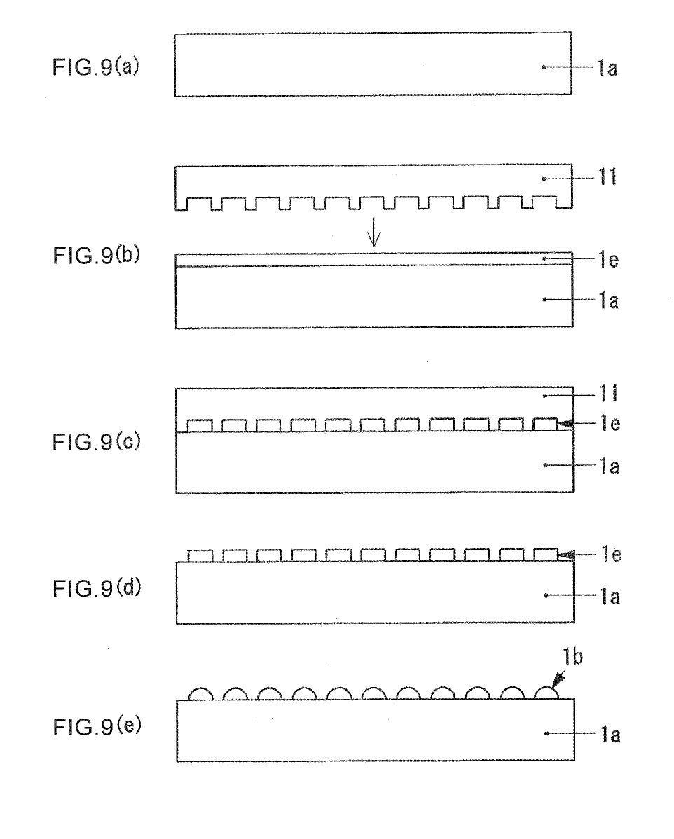

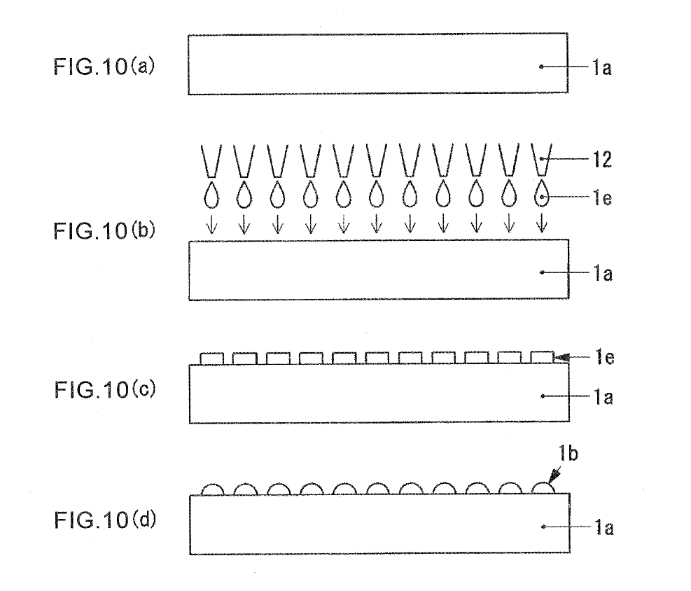

Now, a method for manufacturing the substrate 1 will be described with reference to FIGS. 8 to 11. FIG. 8 is a schematic diagram illustrating a photolithography manufacturing step that is a form according to the method for manufacturing in the present embodiment. FIG. 9 is a schematic diagram illustrating an imprinting manufacturing step that is another form according to the method for manufacturing in the present embodiment. FIG. 10 is a schematic diagram illustrating an ink jet manufacturing step that is another form according to the method for manufacturing in the present embodiment.

As depicted in FIG. 8(a), FIG. 9(a), and FIG. 10(a), first, a flat substrate 1a is prepared. Then, as depicted in FIG. 8(b), FIG. 9(b), and FIG. 10(b), a dielectric 1e containing a photosensitive agent is formed on the plane of the substrate 1a, and the dielectric 1e is patterned to form the protrusions 1b of the dielectric having the desired pattern on the plane of the substrate 1a. In the method for manufacturing depicted in FIG. 8 and FIG. 9, the dielectric is formed into a film with a constant thickness. In the method for manufacturing in FIG. 10, the dielectric is formed into a plurality of protrusions. The flat substrate 1a means that the surface of the substrate 1a on which a dielectric 1e is patterned is formed into a mirror plane and has a surface roughness Ra of approximately 1 nm or less. Furthermore, the desired pattern refers to a pattern of the island-like protrusions 1b.

Patterning the dielectric containing the photosensitive agent allows the desired pattern of the protrusions 1b to be formed on the plane of the substrate 1a. Thus, the pattern can be formed on the plane of the substrate 1a without the need to form any photoresist film (an etching mask for a film to be formed into the protrusions 1b). This leads to a reduction in the number of steps, facilitation of the steps, and a reduction in the costs of the substrate 1 associated with the reduction in the number of steps.

Moreover, individual steps will each be described in detail taking the siloxane resin composition as an example of the dielectric 1e. In a case described below, the substrate 1a is formed of sapphire by way of example (the substrate 1a is hereinafter referred to as the “sapphire substrate 1a” as needed).

In a pre-step for FIG. 8(a), FIG. 9(a), and FIG. 10(a) described above, the sapphire substrate 1a is washed in UV/O3 and then in water, and dehydration baking is performed on the sapphire substrate 1a. Moreover, an HMDS (hexamethyldisilazane) step is executed on the sapphire substrate, which is then baked. Thus, the sapphire substrate 1a is prepared as a flat substrate, as shown in FIG. 8(a), FIG. 9(a), and FIG. 10(a).

Then, in FIG. 8(b) and FIG. 9(b), the siloxane resin composition is uniformly applied on the plane of the sapphire substrate 1a using a spinner.

The siloxane resin composition has high coatability, and thus, using the siloxane resin composition as a formation material for the protrusions 1b allows a regular dielectric with a uniform thickness or height to be formed on the surface of the substrate 1a. Moreover, the siloxane resin composition is not significantly contracted upon being cured, enabling the protrusions 1b to be easily formed on the plane of the substrate 1a so as to have an appropriate height, an appropriate size, and an appropriate pitch as desired. Furthermore, the siloxane resin composition is unlikely to be cracked after curing. Consequently, gaps (voids) are unlikely to occur at the interface between the protrusions 1b and GaN layers (2 to 5) during growth of the GaN layers. Therefore, the light-emitting element 8 can be prevented from being subjected to deteriorated electrical characteristics.

Several methods are available for forming the desired pattern on the plane of the substrate 1a using the siloxane resin composition formed on the plane of the substrate 1a. For example, three methods are available: the above-described photolithography, imprinting, and ink jet printing.

Steps of the photolithography are as follows. As described above, the dielectric 1e is applied on the plane of the substrate 1a to form a film of the dielectric 1e on the plane of the substrate 1a (see FIG. 8(b)). Subsequently, the substrate 1a with the film of the dielectric 1e formed on the plane of the substrate 1a is pre-baked. Then, as depicted in FIG. 8(c), the film of the dielectric 1e is exposed using a mask 10 so as to have the desired pattern. Moreover, the exposed dielectric 1e is developed (see FIG. 8(d)), and the developed dielectric 1e is post-baked. Moreover, as depicted in FIG. 8(e), the post-baked dielectric 1e is performed annealing to form the dielectric 1e with the desired pattern on the plane of the substrate 1a (at the time in FIG. 8(e), the dielectric 1e is formed into the protrusions 1b). In the above-described example, the developed dielectric 1e is performed annealing after being post-baked. However, the present invention is not limited to this. The developed dielectric 1e may be performed annealing without being post-baked.

Steps of the imprinting are as follows. As described above, the dielectric 1e is applied on the plane of the substrate 1a to form a film of the dielectric 1e on the plane of the substrate 1a (see FIG. 9(b)). Subsequently, a mold 11 is pressed against the film of the dielectric 1e, which is then irradiated with light so as to be cured (see FIG. 9(c)). Then, the dielectric 1e is post-baked (see FIG. 9(d)). Moreover, as depicted in FIG. 9(e), the post-baked dielectric 1e is performed annealing to form the dielectric 1e with the desired pattern on the plane of the substrate 1a (at the time in FIG. 9(e), the dielectric 1e is formed into the protrusions 1b).

Steps of the ink jet printing are as follows. Instead of application of the siloxane resin composition using the spinner as described above, application of the dielectric 1e directly on the plane of the substrate 1a through a nozzle 12 is performed to form the desired pattern directly on the plane of the substrate 1a (see FIG. 10(b)). Then, the substrate 1a formed on the plane of the substrate 1a is pre-baked, and the dielectric 1e is further exposed and then post-baked (see FIG. 10(c)). Moreover, as depicted in FIG. 10(d), the post-baked dielectric 1e is performed annealing to form the dielectric 1e with the desired pattern on the plane of the substrate 1a (at the time in FIG. 10(d), the dielectric 1e is formed into the protrusions 1b). In the imprinting or the ink jet printing, the dielectric 1e may be performed annealing without being post-baked.

A light source for exposure in the photolithography is preferably a g-line (wavelength: 436 nm), an h-line (wavelength: 405 nm), or an i-line (wavelength: 365 nm) from a high-pressure mercury lamp, a KrF excimer laser (wavelength: 248 nm), or an ArF excimer laser (wavelength: 193 nm) in order to allow a fine pattern to be formed. Furthermore, the film of the dielectric 1e is classified into a positive type and a negative type, and the positive type is preferable in order to allow a fine pattern to be formed. For the positive type, the exposed dielectric needs to be developed without being baked. When the exposed dielectric 1e is baked at 60 deg C or higher, the siloxane in the exposed part makes condensation reaction and has reduced solubility to a developer, failing to form a pattern. This is not preferable.

For the positive-type siloxane, naphthoquinonediazide-5-sulfonic ester is preferably used as a photosensitive agent.

As an exposure device, a device enabling a reduction projection exposure technique is preferably used in order to enable the pattern to be miniaturized.

Furthermore, as a developer for the photolithography, an agent is used which dissolves the siloxane resin composition. The developer may be an organic solvent or an organic or inorganic alkali. However, the inorganic alkali such as potassium hydroxide (KOH) is unavoidably mixed into the subsequent step, and thus, TMAH (Tetra-Methyl-Ammonium-Hydroxide), which is an organic alkali, is most preferable.

As described above, for all of the photolithography, the imprinting, and the ink jet printing, the dielectric 1e is further post-baked after being patterned. The post-baking allows a rinsing liquid attached to the substrate 1a and the dielectric 1e to be removed due to heat. Moreover, the post-baked dielectric 1e is performed annealing to form the dielectric 1e with the desired pattern on the plane of the substrate 1a.

When the post-baking is performed within a temperature range of 100 deg C or higher and 400 deg C or lower, the flowability of the dielectric 1e can be enhanced to enable the entire pattern of the dielectric 1e or a part of the top part/side parts to be shaped into a curved shape. Thus, the light extraction efficiency of the light-emitting element 8 can be enhanced. Moreover, compared to protrusions with a trapezoidal or rectangular sectional shape (for example, protrusions 109), the protrusions 1b shaped into curved shapes serve to shorten the time needed to grow the GaN layers (2 to 5) in the lateral direction during formation of the GaN layers and the like. Consequently, the time needed to grow the GaN layers can be shortened. At lower than 100 deg C, the flowability of the dielectric 1e is insufficient, precluding the entire pattern of the dielectric 1e or a part of the top part/side parts from being shaped into a curved shape. Furthermore, at higher than 400 deg C, the flowability of the dielectric 1e is enhanced, precluding a desired resolution pattern from being obtained.

Annealing the dielectric 1e formed into the desired pattern enables the desired pattern to be formed into any side shape on the plane of the substrate 1a without the need to form any photoresist film (an etching mask for a film to be formed into the protrusions 1b). Moreover, when the photosensitive agent component is removed as a result of the annealing, organic components can be prevented from being mixed into the light-emitting element 8 such as the GaN layers (2 to 5). The removal of the photosensitive agent component refers to the removal based on evaporation of the photosensitive agent liquefied by the annealing.

Moreover, using the photolithography to form the desired pattern enables the pattern to be formed on the plane of the substrate 1a without the need to form any photoresist film (an etching mask for a film to be formed into the protrusions 1b). This leads to a reduction in the number of steps, facilitation of the steps, and a reduction in the costs of the substrate 1 associated with the reduction in the number of steps. Moreover, the need for a short time for the photolithography step allows the substrate 1 with the desired pattern on the plane thereof to be produced in a short time.

The imprinting will be described in further detail. A material for the mold 11 may be a material such as quartz which allows ultraviolet rays to appropriately pass through. A method for producing a quartz mold is as follows. First, quartz is prepared, and then, a resist is applied on the quartz substrate. Normal photolithography or electron beam lithography is used to expose and form the resist into a pattern of island shapes, and the pattern is developed. Then, Al is deposited to a thickness of approximately 100 nm and lifted off. Moreover, with the Al as a mask, the quartz is etched down to a predetermined depth using an RIE (Reactive Ion Etching) device and CHF3 (trifluoromethane). The predetermined depth is the same as the height of the protrusions 1b. Unwanted Al remaining after the etching is removed with a phosphoric acid. Finally, the quartz is washed in pure water and dried to complete the quartz mold.

With the mold 11 as described above kept pressed against the dielectric 1e, the dielectric 1e is irradiated with ultraviolet rays though the mold 11 and cured. In regard to a direction in which the ultraviolet rays are radiated, the ultraviolet rays may be radiated from the mold 11 side or from the sapphire substrate 1a side because the sapphire substrate 1a is transparent. When the ultraviolet rays are radiated from the substrate 1a side, the material for the mold 11 need not necessarily be transparent, and thus, a material other than quartz, for example, an opaque material such as silicon, may be used. As a transparent material, sapphire may be used for the mold 11.

The process may also be executed in a vacuum atmosphere so as to avoid incorporating bubbles into each piece of the dielectric 1e when the mold 11 is pressed against the dielectric 1e. The example has been illustrated where optical nanoimprinting is used as the imprinting. Alternatively, thermal nanoimprinting may also be used in which the dielectric 1e is thermally cured.

After the island-shaped pieces of the dielectric 1e are cured, the mold 11 is pulled apart, and the unwanted dielectric remaining in parts of the mold 11 corresponding to the protrusions (parts of the island shapes other than the dielectric 1e) is removed using the oxygen RIE device.

As described above, using the nanoimprinting to form the desired pattern allows a pattern of the protrusions 1b with a desired size, a desired pitch, and a desired height to be formed on the plane of the substrate 1a using simple facilities and at low costs.

Furthermore, using the ink jet printing to form the desired pattern allows the pattern to be directly formed, enabling an increase in the degree of freedom for the type of the pattern of the protrusions 1b.

Among the above-described photolithography, imprinting, and ink jet printing, the photolithography is preferable due to its highest general-purpose property.

Moreover, the annealing is performed within a temperature range of 600 deg C or higher and 1,700 deg C or lower to allow the photosensitive agent component to be removed from the protrusions 1b. Thus, organic components can be prevented from being mixed into the light-emitting element 8 such as the GaN layers (2 to 5). Moreover, growth of the GaN layer on the protrusions 1b can be prevented or made difficult. Suppressing the growth of the GaN layer on the protrusions 1b allows the FACELO growth mode to be achieved. Consequently, GaN layers with a reduced dislocation density can be formed. A temperature of lower than 600 deg C precludes the use of any of SiO₂, TiO₂, and ZrO₂ as a main component. Furthermore, a temperature of higher than 1,700 deg C exceeds the melting point of any of SiO₂, TiO₂, and ZrO₂ as a protrusion 1b main component, possibly causing the shape of the protrusions 1b to be distorted. This is not preferable.

Now, a method for manufacturing the light-emitting element 8 will be described. The light-emitting element 8 is manufactured by, first, preparing the substrate 1 with the desired pattern on the plane thereof which has been manufactured by the above-described method for manufacturing, and forming at least one of a GaN layer, an AlN layer, and an InN layer on the protrusions 1b and the substrate 1a.

The GaN layers 2 to 5 depicted in FIG. 1 may be grown by a well-known method such as a epitaxial growth or different film formation methods and/or conditions may be adopted to form the respective GaN layers 2 to 5. The epitaxial growth includes homo-epitaxial growth and hetero-epitaxial growth. Other film formation methods include liquid phase film formation methods such as plating, but vapor phase film formation methods such as sputtering and CVD (Chemical Vapor Deposition) are preferably used. Moreover, when semiconductor layers such as the group 3 to 5 nitride compound semiconductor layers are formed in order to manufacture the light-emitting element 8, a vapor phase film formation method is more preferably utilized such as MOCVD (Metal Organic Chemical Vapor Deposition), MOVPE (Metal Organic Vapor Phase Epitaxy), HYPE (Hydride Vapor Phase Epitaxy), or MBE (Molecular Beam Epitaxy). When the material used for the substrate 1b is an inorganic material such as sapphire, a material configuring each of the semiconductor layers is preferably also an inorganic material such as a metal material, a metal oxide material, or an inorganic semiconductor material. All the layers are preferably configured of these inorganic materials. However, when the MOCVD is used as a film formation method, an organic substance derived from organic metal may be contained in the inorganic material in the semiconductor layers.

First, a buffer layer of GaN or AlN is formed on a plane of the sapphire substrate 1 that is closer to the protrusions 1b. Then, the n-GaN layer 2, the InGaN light emitting layer (active layer) 3, the p-type AlGaN clad layer 4, and the p-type GaN contact layer 5 are formed in this order. Subsequently, predetermined post-machining is performed to produce the light-emitting element 8.

Since the protrusions 1b are configured of the dielectric, no crystal plane with a particular plane orientation is exposed from the surface of each of the protrusions 1b. Thus, a nucleus serving as a start point for growth of the n-GaN layer 2 is difficult to generate. That is, since no crystal plane with a particular plane orientation is exposed from the side parts of the protrusion 1b, crystal growth of the GaN layer from the side parts of the protrusion 1b is suppressed. Furthermore, at least a part (for example, a top part) of the protrusion 1b is formed into a curved shape and has substantially no flat portion or has a very narrow flat portion, preventing growth of the GaN layer. However, a crystal plane with a particular plane orientation is exposed all over the plane of the substrate 1 (for example, the C plane of sapphire), a nucleus of GaN is easy to generate, allowing the n-GaN layer 2 to grow.

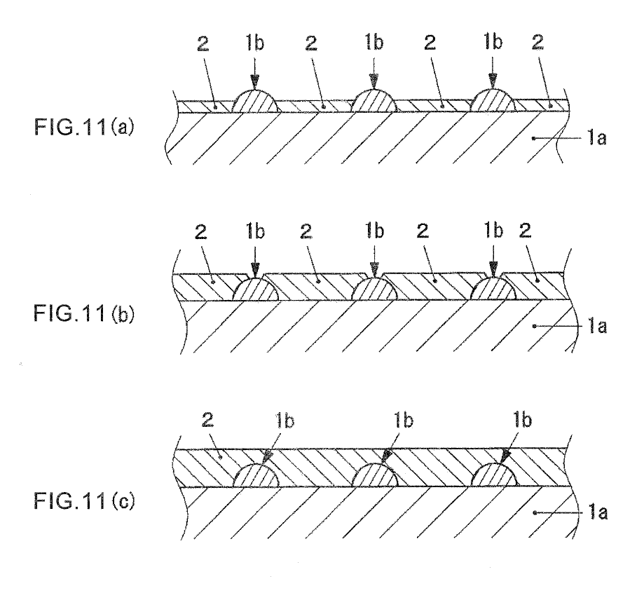

Therefore, as depicted in FIG. 11(a), the growth of the n-GaN layer 2 starts at the surface of the substrate 1a between the protrusions 1b, that is, at flat parts that are not the protrusions 1b. The n-GaN layer 2 grows in the lateral direction (horizontal direction) as the thickness of the n-GaN layer 2 increases. As depicted in FIG. 11(b), the n-GaN layer 2 progressively covers the side part and the top part of the protrusion 1b. Finally, when the thickness of the n-GaN layer 2 is equal to or larger than the height of the protrusion 1b, the surface of the substrate 1a and the pattern of the protrusions 1b is covered with the n-GaN layer 2 as depicted in FIG. 11(c). Then, only a flat surface of the n-GaN layer 2 is observed as viewed in a plane direction.

Therefore, the side parts of the protrusion 1b correspond to lateral growth areas for the n-GaN layer 2, enabling prevention of possible dislocation from the side parts of the protrusion 1b. Moreover, since at least a part (for example, the top part) of the protrusion 1b is formed into a curved shape, the protrusion 1b has substantially no flat portion or has a very narrow flat portion. Therefore, the growth of the n-GaN layer 2 from the protrusion 1b can be suppressed or prevented, allowing prevention of possible dislocation in the n-GaN layer 2 near the protrusion 1b. Thus, this configuration enables a reduction in the number of threading dislocations compared to a configuration in which the GaN layers are grown on a flat substrate.

Moreover, the formation of the buffer layer of GaN or AlN allows prevention of a variation in film quality or thickness in a film thickness direction of the n-GaN layer 2.

Moreover, after the GaN layers 3 to 5 are formed by a well-known method, the p-type electrode 6 is formed by electron beam deposition. Furthermore, ICP-RIE is used to etch an area of the n-GaN layer 2 where the InGaN light emitting layer 3 is not formed, exposing the n-GaN layer 2. Then, the n-type electrode layer 7 of a Ti/Al laminate structure is formed on the exposed n-GaN layer 2 by electron beam deposition. The p-type metal electrode 9 of Ti/Al is then formed on the p-type electrode 6. The light-emitting element 8 is thus produced. Metal such as Ni, Au, Pt, Pd, or Rh may be used for the p-type electrode 6 and the n-type electrode layer 7.

The protrusions 1b formed on the surface of the substrate 1a each allow the light scattering effect to be exerted. Therefore, a portion of light absorbed inside the light-emitting element 8 can be extracted to the outside of the substrate 1a and the InGaN light emitting layer 3, allowing the light extraction efficiency of the light-emitting element 8 to be improved.

Moreover, patterning the dielectric containing the photosensitive agent enables the desired pattern of the protrusions 1b to be formed on the plane of the substrate 1a. Thus, the pattern can be formed on the plane of the substrate 1a without the need to form any photoresist film (an etching mask for a film to be formed into the protrusions 1b). This leads to a reduction in the number of steps, facilitation of the steps, and a reduction in the costs of the light-emitting element 8 associated with the reduction in the number of steps. Furthermore, the light-emitting element 8 with the light extraction efficiency improved can be manufactured.

Furthermore, the surface of the substrate 1a may be dry- or wet-etched using, as a mask, the pattern of the protrusions 1b of the dielectric, to form an island-shaped pattern directly on the surface of the substrate 1a.

The present invention will be described below using Example 1. However, the present invention is not limited to Example 1 described below.

### Example 1

### Method for Manufacturing

First, a flat sapphire substrate was prepared in which the substrate surface was a C plane formed into a mirror plane and having a surface roughness Ra of 1 nm. The sapphire substrate was washed in UV/O₃ for five minutes and then in water. Dehydration baking was performed on the sapphire substrate at 130 deg C for three minutes using a hot plate. Moreover, an HMDS (hexamethyldisilazane) agent was applied to the surface of the dehydration-baked sapphire substrate using a spinner in two steps, one at 300 rpm for 10 seconds and the other at 700 rpm for 10 seconds. Subsequently, the sapphire substrate was baked at 120 deg C for 50 seconds using the hot plate.

Then, a film containing the siloxane resin composition was formed on the plane of the sapphire substrate using a spinner in two steps, one at 700 rpm for 10 seconds and the other at 1,500 rpm for 30 seconds; the siloxane resin composition was used as a dielectric having a lower refractive index than GaN, which is 2.4 in refractive index, and containing as a photosensitive agent naphthoquinonediazido-5-sulfonic ester. As a result, a siloxane resin composition film with a thickness of 1.55 μm was formed. As the siloxane resin composition, positive-type photosensitive siloxane ER-S2000 manufactured by Toray industries, Inc. (a fricative-index-1.52 (632.8 nm) prism coupler method for a pre-baked film) is used.

In the present example, the photolithography was adopted as a method for forming the desired pattern on the sapphire substrate plane using the above-described siloxane resin composition film. The sapphire substrate having the siloxane resin composition film formed on the plane thereof was pre-baked at 110 deg C for three minutes using the hot plate. Then, pattern exposure was performed on the siloxane resin composition film. In the present example, a positive mask was produced so as to allow formation of a pattern in which the protrusions had a round flat shape with a diameter of 4.9 μm and were arranged at a pitch of 6.0 μm, and the siloxane resin composition film was exposed. As a light source for the exposure, broad light was used which contained a g-line, an h-line, and an i-line and had light irradiation energy of 65 mJ/cm² in terms of i-lines (g-line=436 nm, h-line=405 nm, i-line=365 nm). Furthermore, the siloxane resin composition film was of the positive type, and as an exposure device, a contact exposure device was used.

Moreover, the exposed siloxane resin composition film was developed. As a developer, 2.38 wt %-TMAH was used. The siloxane resin composition film was immersed in the developer for 60 seconds, Subsequently, the sapphire substrate and the developed siloxane resin composition were post-baked at 230 deg C for three minutes using the hot plate.

Moreover, after the post-baking, the developed siloxane resin composition on the sapphire substrate was performed annealing in an air atmosphere at 1,000 deg C for one hour to form, on the plane of the sapphire substrate, protrusions in the desired pattern and with the desired side shape.

—Protrusions—

The protrusions manufactured in the above-described steps were checked and determined to have a pattern described below and to contain. SiO₂.

Flat shape: round shape
Diameter of the round shape: 4.9 μm

### Height: 0.47 μm

### Pitch: 6.0 μm

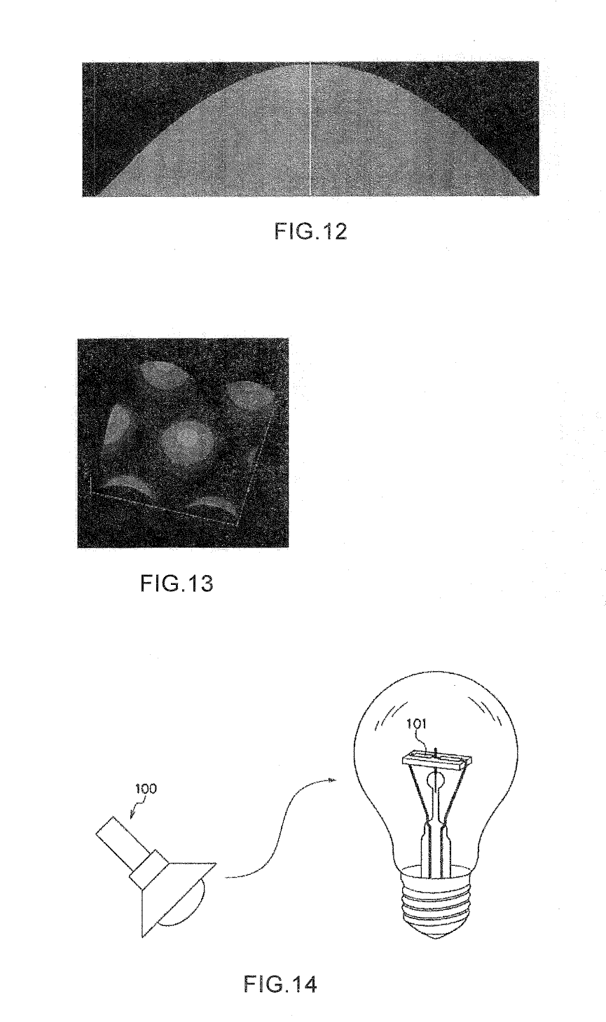

Side shape: curved shape formed so as to generally have a curved surface (see FIG. 12 and FIG. 13)

### Example 2

### Method for Manufacturing

The protrusions in the desired pattern and with the desired side shape were formed on the plane of the sapphire substrate as is the case with Example 1 except that the positive-type photosensitive siloxane ER-S2000 manufactured by Toray Industries, Inc., which is a siloxane resin composition, was changed to positive-type photosensitive titanium-oxide-containing siloxane ER-53000 manufactured by Toray Industries, Inc. A refractive-index-1.78 (632.8 nm) prism coupler method for a pre-baked film was adopted.

—Protrusions—

The protrusions manufactured in the above-described steps were checked and determined to have a pattern described below and to contain TiO₂.

Flat shape: round shape
Diameter of the round shape: 4.9 μm

### Height: 1.00 μm

### Pitch: 6.0 μm

Side shape: curved shape formed so as to generally have a curved surface (see FIG. 12 and FIG. 13)

### Example 3

### Method for Manufacturing

The protrusions in the desired pattern and with the desired side shape were formed on the plane of the sapphire substrate as is the case with Example 1 except that the positive-type photosensitive siloxane ER-S2000 manufactured by Toray Industries, Inc., which is a siloxane resin composition, was changed to positive-type photosensitive zirconium-oxide-containing siloxane ER-S3100 manufactured by Toray Industries, Inc. A refractive-index-1.64 (632.8 nm) prism coupler method for a pre-baked film was adopted.

—Protrusions—

The protrusions manufactured in the above-described steps were checked and determined to have a pattern described below and to contain ZrO₂.

Flat shape: round shape
Diameter of the round shape: 4.9 μm

### Height: 1.50 μm

### Pitch: 6.0 μm

Side shape: curved shape formed so as to generally have a curved surface (see FIG. 12 and FIG. 13)

### Comparative Example

A comparative example will be described below. In the comparative example, an SiO₂ film was formed by plasma CVD, and a photoresist film was formed on the SiO₂ film and exposed and developed as is the case with Example 1. Thus, a pattern similar to the pattern in Example 1 was formed on the photoresist film. The SiO₂ film was dry-etched using the patterned photoresist film as a mask.

The finished protrusions were checked for the pattern and the amount of SiO₂ contained in the protrusions. The results of the check were similar to the results for the protrusions in Example 1.

<Evaluation>

For Example 1 and the comparative example, the number of steps needed and a lead time were evaluated. As a result, for Example 1, the number of steps needed was 8, and the lead time was 70 minutes. On the other hand, for the comparative example, the number of steps needed was 9, and the lead time was 110 minutes. The results of the evaluation indicate the present example enables a reduction in the number of steps and in lead time. In the case of mass production and an increased diameter of the substrate, the comparative example limits the number of wafers treated due to device sizes for the film formation step and dry etching step for the SiO₂ film. This results in a more significant difference in lead time.

The above-described substrate and light-emitting element can be applied to the following devices, equipment, and the like. For example, provision of the light-emitting element can be utilized as a light source 101 for lighting 100 or as a built-in light source for equipment or the like, as depicted in FIG. 14. These light sources are particularly suitable for light ranging from blue visible light to ultraviolet light when the light-emitting element is configured of nitrogen (N) included in the group V elements. Thus, the light sources can be utilized for equipment or the like which is needed to emit blue visible light or ultraviolet light. For example, the light-emitting element can be utilized as a light source for lighting, a traffic light, a floodlight, and an endoscope that are used to emit blue light (short wavelength), a light source 201 for one of the three primary colors of a color display 200 (see FIG. 15), a light source for optical pickup, and a light source for a sterilization box emitting IN light, a refrigerator, and the like. Furthermore, the light-emitting element is combined with a surface coated with a fluorescent paint to generate white color or an incandescent color. Consequently, the combination can be utilized as a light source for lighting equipment such as a fluorescent light (for example, lighting for plant cultivation), a backlight of a display, vehicular lamps, a projector, and camera flash. Of course, the light-emitting element in the present application is not limited to the nitride-based compound semiconductors, and thus, the application range of the light-emitting element is not limited to the above-described application range.

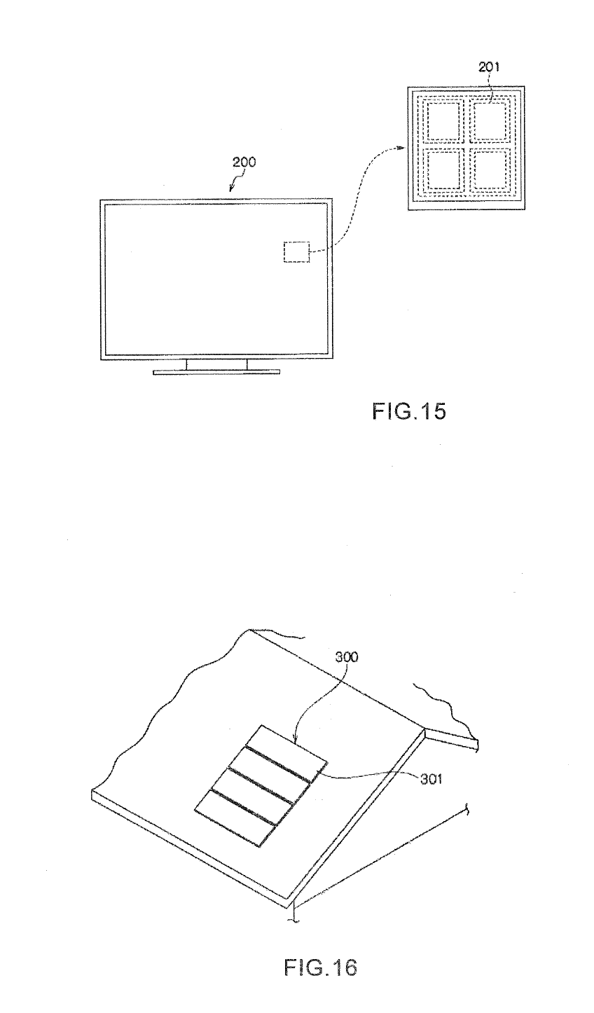

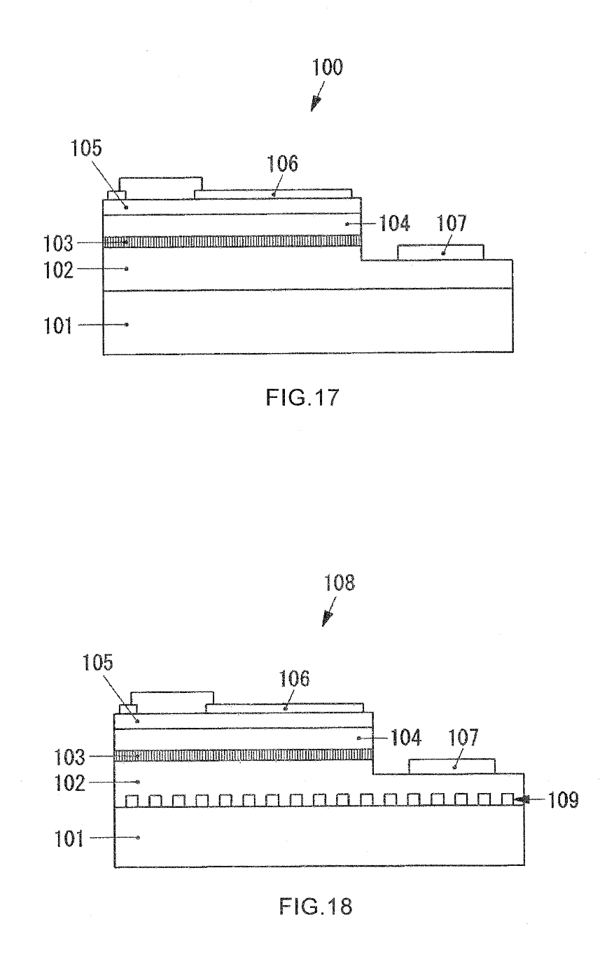

Furthermore, as depicted in FIG. 16, the substrate in the present application can be utilized not only as a light-emitting element but also as a light receiving element that receives light traveling in various directions. The substrate can thus be utilized as a substrate for a photodiode or a substrate 301 for a solar cell or a solar generation panel 300.

The present invention is not limited to the illustrated examples and application examples and can be implemented by being configured within a range that does not depart from the contents recited in the claims. That is, the present invention is specifically illustrated and described in connection mainly with the particular embodiments, but those skilled in the art may make many variations to the above-described embodiments in terms of quantities and other detailed configurations without departing from the scope of technical concepts and objects of the present invention.

### REFERENCE SIGNS LIST

1 Substrate having desired pattern on plane thereof
1a Substrate
2b Protrusion
2 N-type GaN contact layer (n-GaN layer)
3 InGaN light emitting layer (active layer)
4 P-type AlGaN clad layer
5 P-type GaN contact layer
6 P-type electrode
7 N-type electrode layer
8 LED light-emitting element
9 Metal electrode
10 Mask
11 Mold
12 Nozzle
13 Trapezoidal protrusion
14 Rectangular protrusion
100 Lighting device
101 Light source (light-emitting element)
200 Display device
201 Light source (light-emitting element)
300 Solar cell
301 Substrate

1. A method for manufacturing a substrate comprising:
preparing a flat substrate;
forming a dielectric containing a photosensitive agent on a plane of the substrate; and
patterning the dielectric to form the dielectric having a desired pattern on the plane of the substrate.

2. The method for manufacturing a substrate according to claim 1, wherein, annealing is performed on the dielectric to form the dielectric having the desired pattern on the plane of the substrate after the dielectric is patterned.

3. The method for manufacturing a substrate according to claim 2, wherein the dielectric is post-baked after the dielectric is patterned but before the annealing.

4. The method for manufacturing a substrate according to claim 3, wherein the post-baking is performed within a temperature range of 100 deg C or higher and 400 deg C or lower.

5. The method for manufacturing a substrate according to claim 2, wherein the annealing is performed within a temperature range of 600 deg C or higher and 1700 deg C or lower.

6. The method for manufacturing a substrate according to claim 1, wherein the dielectric is any of a siloxane resin composition, a titanium oxide-containing siloxane resin composition, and a zirconium oxide-containing siloxane resin composition.

7. The method for manufacturing a substrate according to claim 2, further comprising:
applying the dielectric on the plane of the substrate to form the dielectric on the plane of the substrate;
then pre-baking the substrate having the dielectric that has been formed on the plane of the substrate;
then exposing the dielectric with the desired pattern by using a mask;
then developing the exposed dielectric, and
performing the annealing on the dielectric to form the dielectric having the desired pattern on plane of the substrate.

8. The method for manufacturing a substrate according to claim 2, further comprising:
directly patterning the dielectric on the plane of the substrate according to the desired pattern;
then pre-baking the substrate having the dielectric formed on the plane of the substrate;
then exposing the dielectric, and
performing the annealing on the dielectric to form the dielectric having the desired pattern on the plane of the substrate.

9. The method for manufacturing a substrate according to claim 2, further comprising:
applying the dielectric on the plane of the substrate to form the dielectric on the plane of the substrate;
then pressing a mold against the dielectric to cure the dielectric, and
performing the annealing on the dielectric to form the dielectric having the desired pattern on the plane of the substrate.

10. A method for manufacturing a substrate comprising:
preparing the substrate according to claim 1; and
performing an etching treatment on a surface of the substrate in use of the pattern as a mask to form the desired pattern on the surface of the substrate.

11. A method for manufacturing a light-emitting element comprising:
preparing the substrate according to claim 1; and
forming at least one of a GaN layer, an MN layer and an InN layer on protrusions and the substrate.

12. A substrate comprising a pattern including island-shaped protrusions on a flat plane of the substrate, the protrusions being configured of a dielectric.

13. The substrate according to claim 12, wherein the protrusions at least partly have a curved shape.

14. The substrate according to claim 12, wherein a dielectric configuring the protrusions contains any of SiO₂, TiO₂, and ZrO₂ as a main component.

15. The substrate according to claim 12, wherein the protrusions have a curved shape generally, no distinction between a top part and side parts, and a curved surface without a flat face.

16. The substrate according to claim 15, wherein the protrusions are semi-spherical.

17. The substrate according to claim 12, wherein the protrusions have a round or elliptical flat shape.

18. The substrate according to claim 12, having the desired pattern on the surface of the substrate.

19. A light-emitting element comprising the substrate according to claim 12, and at least one of a GaN layer, an MN layer and an InN layer formed on the protrusions and the substrate.

20. A light source comprising the light-emitting element according to claim 19.

21. A display comprising the light-emitting element according to claim 19.

22. A solar cell comprising the substrate according to claim 12.
